(19) United States
(12) Patent Application Publication
(10) Pub. No.: US 2012/0292624 A1
(43) Pub. Date: Nov. 22, 2012

(54) ARRAY SUBSTRATE, METHOD FOR FABRICATING THE SAME AND LIQUID CRYSTAL DISPLAY DEVICE

(75) Inventors: Jing LV, Beijing (CN); Yuting ZHANG, Beijing (CN); Yang SUN, Beijing (CN)

(73) Assignee: BOE TECHNOLOGY GROUP CO., LTD., Beijing (CN)

(21) Appl. No.: 13/475,422

(22) Filed: May 18, 2012

(30) Foreign Application Priority Data
May 20, 2011 (CN) 201110131453.4

(51) Int. Cl. H01L 33/08

(52) U.S. Cl. 257/59; 438/34; 257/72; 257/E33.053

(57) ABSTRACT

The disclosed technology is directed to an array substrate, a method for fabricating the same and a liquid crystal display device. The array substrate comprises an electro-static discharge (ESD) circuit region and a pixel region. The method comprises: adjusting the amount of light for exposing so that the amount of light for exposing corresponding to the pixel region is identical to that corresponding to the ESD circuit region; and forming a channel of a thin film transistor (TFT) in the ESD circuit region and a channel of a TFT in the pixel region by a pattering process, wherein the channel of the TFT in the ESD circuit region comprises a plurality of sub-channels arranged in parallel, and each of the sub-channels of the TFT in the ESD circuit region has the same length as the length of the channel of the TFT in the pixel region.

### BACKGROUND

Embodiments of the disclosed technology relate to an array substrate comprising an electro-static discharge (ESD) circuit, a method for fabricating the same, and a liquid crystal display device comprising the array substrate.

With fast development of thin film transistor liquid crystal display devices (TFT-LCDs), there is great competition among the TFT-LCD products and producers.

For purpose of reducing the costs and increasing the yield of TFT-LCDs, there is a need for further simplifying the process and reducing the number of steps. Four-mask technologies are the typical methods which have been developed for reducing the number of steps, saving raw materials and increasing yield. There are a variety of four-mask technologies, and the single slit mask (SSM) technology is significant among the variety of four-mask technologies. In the SSM technology, light is not completely transmitted through the portion of the photo mask corresponding to the channel of the TFT by employing the light diffraction phenomenon, so that a partially-exposed gray tone region having a certain gray tone thickness is formed in the exposed and then developed photoresist pattern. The four-mask process can be achieved due to the presence of the gray tone region. In addition to the above advantages, the SSM technology also has a function of improving the property of the product by reducing the channel length of the TFT. Therefore, there is an increasing attention on further development of the SSM technology.

In general, the turn-on current Ion of a TFT is proportional to the ratio of width to length of the channel (i.e., W/L, where W is the channel width of the TFT, and L is the channel length, that is, the distance between the source electrode and the drain electrode. as shown in FIG. 1). As W is increased, the turn-on current Ion of the TFT will be increased also and the driving capability will be enhanced. However, the gate-source capacitance Cgs and the gate-drain capacitance Cgd are increased accordingly, which results in the increase of the loads on the gate and the data lines. As L is decreased, the turn-on current Ion of the TFT will be increased also and the driving capability will be enhanced, which is identical to the case in which W is increased. However, the gate-source capacitance Cgs and the gate-drain capacitance Cgd are reduced, and thus the loads on the data line are reduced.

Generally, the channel length of a TFT is small, on the order of 2.0 μm to 3.0 μm. Furthermore, the channel length of a TFT in the pixel region for displaying is different from channel length of a TFT in the ESD circuit region. When the SSM technology is employed in fabricating, the gray tone photoresist (GT PR) in the partially-exposed region is highly sensitive to the amount of light for exposing, so there is an issue in the fabricating process by employing SSM technology to ensure the thickness of GT PR in the pixel region is identical to that in the ESD circuit region.

FIG. 1 is a schematic diagram showing a conventional photo mask design of a channel in the ESD circuit region by employing the multiple slits interference phenomenon. FIG. 2 is a schematic diagram showing an equivalent conventional circuit of the ESD circuit.

As shown in FIG. 1 (the shadowed part indicates one channel), when the photo mask for forming the channel in the ESD circuit region based on the multiple slits diffraction phenomenon is employed, the multiple slits can diffract light, and the portion of the photoresist corresponding to the channels have the same thickness substantially. There are two defects in this solution, one of which is that, when the photo mask for forming channels in the ESD circuit region based on the multiple slits interference phenomenon and the photo mask for forming the channel in the pixel region based on the single slit diffraction phenomenon are used simultaneously, it is impossible to ensure the light transmissivity of the two photo masks to be identical to each other, and thus it is impossible to ensure the GT PR thickness of the channels in the pixel region and that in the ESD circuit region to be identical to each other. As a result, it is difficult to control the fabrication process, and the yield of the process may be reduced accordingly. The other defect is that, when the multiple slits interference is employed, there may be a ripple occurred in the part of the photoresist corresponding to the channels. In other words, the unevenness of the photoresist may occur. As a result, the difficulty to control the process may be increased further, and the yield of the process may be reduced accordingly.

### SUMMARY

According to a first aspect of the disclosed technology, there is provided a method for fabricating an array substrate, the array substrate comprising an electro-static discharge (ESD) circuit region and a pixel region, the method comprising: adjusting the amount of light for exposing of an exposure device so that the amount of light for exposing corresponding to the pixel region is identical to that corresponding to the ESD circuit region; and forming channels of a thin film transistor (TFT) in the ESD circuit region and a channel of a TFT in the pixel region by a pattering process, wherein the channel of the TFT in the ESD circuit region comprises a plurality of sub-channels arranged in parallel, and each of the sub-channels of the TFT in the ESD circuit region has the same length as the length of the channel of the TFT in the pixel region.

According to a second aspect of the disclosed technology, an array substrate is provided. The array substrate comprises: a pixel region comprising at least one TFT having a channel; and an ESD circuit region comprising at lest one TFT having a plurality of sub-channels connected in series, wherein each of the sub-channels of the TFT in the ESD circuit region has the same length, and the length of each of the sub-channels is identical to the length of the channel of the TFT in the pixel region.

According to a third aspect of the disclosed technology, a liquid crystal display device is provided. The liquid crystal display device comprises an array substrate. The array substrate comprises: a pixel region comprising at least one TFT having a channel; and an ESD circuit region comprising at lest one TFT having a plurality of sub-channels connected in series, wherein each of the sub-channels of the TFT in the ESD circuit region has the same length, and the length of each of the sub-channels is identical to the length of the channel of the TFT in the pixel region.

Further scope of applicability of the disclosed technology will become apparent from the detailed description given hereinafter. However, it should be understood that the detailed description and specific examples, while indicating preferred embodiments of the disclosed technology, are given by way of illustration only, since various changes and modifications within the spirit and scope of the disclosed technology will become apparent to those skilled in the art from the following detailed description.

### BRIEF DESCRIPTION OF THE DRAWINGS

The disclosed technology will become more fully understood from the detailed description given hereinafter and the accompanying drawings which are given by way of illustration only, and thus are not limitative of the disclosed technology and wherein:

FIG. 1 is a schematic diagram showing a conventional photo mask design of a channel in the ESD circuit region by employing the multiple slits interference phoneme.

FIG. 2 is a schematic diagram showing an equivalent conventional circuit of the ESD circuit.

FIG. 3 is a schematic diagram showing a photo mask design of channels in an ESD circuit region by employing the single slit diffraction phenomenon in an embodiment of the disclosed technology.

FIG. 4 is a schematic diagram showing an equivalent circuit of the ESD circuit in the embodiment of the disclosed technology.

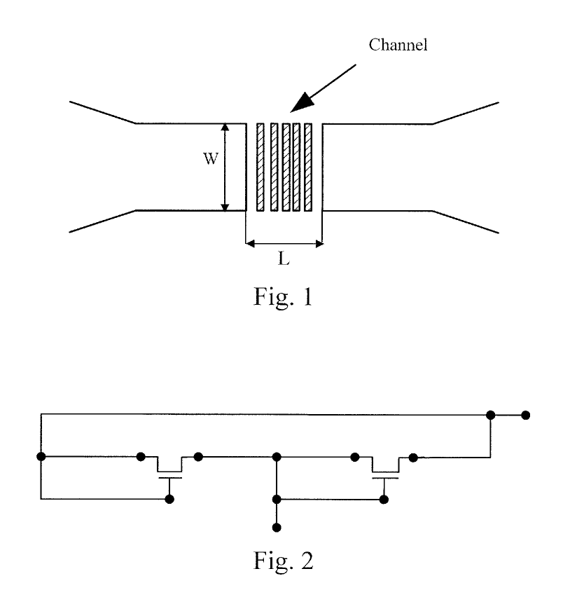

### DETAILED DESCRIPTION

Hereinafter, the embodiments of the disclosed technology will be described in detail with reference to the accompanying drawings so that the objects, technical solutions and advantages of the embodiments of the disclosed technology will become more apparent. It should be noted that the embodiments described below merely are a portion of but not all of the embodiments of the disclosed technology, and thus various modifications, combinations and alterations may be made on basis of the described embodiments without departing from the spirit and scope of the disclosed technology.

The channel or a TFT in an ESD circuit and the method for fabricating the same according to embodiments of the disclosed technology are described in detail.

Firstly, it should be noted that the channel of the TFT in the ESD circuit region is formed by employing the single slit diffraction phenomenon in an embodiment of the disclosed technology rather than the multiple slits interference phenomenon. In other words, both the channels in the ESD circuit region and the channels in the pixel region are formed by employing the single slit diffraction phenomenon.

The array substrate for a liquid crystal display device can comprise a pixel region located in the central portion of the array substrate and an ESD circuit region located on the periphery of the array substrate. The pixel region can comprise a plurality of pixels, each of which comprises at least one TFT which functions as a switching element of the pixel. The ESD circuit region can comprise at leas one TFT device as necessary.

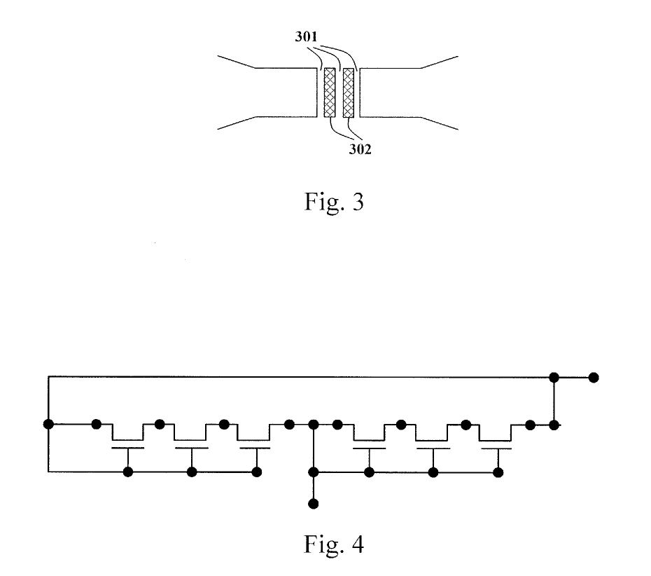

In the following, the embodiments of the disclosed technology will be described in detail with reference to FIGS. 3 and 4. FIG. 3 is a schematic diagram showing a photo mask design of channels in an ESD circuit region by employing the single slit diffraction phenomenon in an embodiment of the disclosed technology. FIG. 4 is a schematic diagram showing an equivalent circuit of the ESD circuit in the embodiment of the disclosed technology.

In the embodiment of the disclosed technology, as shown in FIG. 3, the channel(s) in the ESD circuit region and the channel(s) in the pixel region can be formed in same a pattering process by employing the single slit diffraction phenomenon, and each of the sub-channels 301 (which is separated from each other by an electrode 302) of a channel in the ESD circuit region has the same length as that of a channel in the pixel region. That is, in the photo mask, the sub-channels in the ESD circuit region have the same length, and the length of each sub-channel in the ESD circuit region is equal to the length of the channel in the pixel region. The channels in the pixel region and the sub-channels in the ESD circuit region can have the same amount of light passing in the exposing process based on the single slit diffraction phenomenon, by designing the channels or the sub-channels having the same size in the photo masks. Therefore, the channels in the pixel region and sub-channels in the ESD circuit region can have a same GT PR thickness. In this manner, upon performing the four-mask patterning process, the light amount of the exposure device can be adjusted according to a same slit size. An exemplary process may comprise: adjusting the amount of light exposure in the exposure process for the pixel region and the ESD circuit region with the same amount light by the exposure device. The adjustment of the light amount may be differently performed depending on the particular exposure devices, which is well known for those skilled in the relevant technical field, thus the detailed description is omitted here.

It should be noted that FIG. 3 shows only the case where three sub-channels are formed for a channel in the ESD circuit region, but the disclosed technology is not limited thereto, and two or more sub-channels can be formed in the ESD circuit region as necessary.

In the embodiments of the disclosed technology, a photo mask is also provided. The photo mask can comprise an ESD circuit region and a pixel region. The channel of a TFT in the ESD circuit region may comprise a plurality of sub-channels, and each of the sub-channels has the same length as the channel length of a TFT in the pixel region. After the photoresist for forming the channels of the TFT in the ESD circuit region is exposed and developed by using the photo mask, the portions of the photoresist corresponding to respective sub-channels 301 have the same thickness d1, and the portions of the photoresist corresponding to the electrodes 302 located between the sub-channels 301 and the portions of the photoresist corresponding to the source-drain electrodes on both sides of the sub-channels may have the same thickness d2, which is larger than d1.

In the embodiment of the disclosed technology, it is realized that each of the sub-channels in the ESD circuit region has the same length as the channel length in the pixel region by adjusting the amount of the exposing light to ensure the same amount of light transmitted through the channels of the ESD circuit region and the pixel region in an exposing process. Therefore, when the SSM technology is employed, as compared with the common 4-mask technology, the turn-on current (Ion) of a TFT can be improved by 30% or more, and the capacitances Cgd and Cgs can be reduced by 15% or more.

The problem in a conventional technology that the amount of the transmitted light in the pixel region is different from that in the ESD circuit region so that the GT PR thickness in the pixel region is significantly different from that in the ESD circuit region because the TFT channel in the pixel region is designed to have the length different from the length of the TFT channel in the ESD circuit region, can be solved by the method set forth in the embodiments of the disclosed technology. Since it is realized that the GT PR thickness of a TFT in the ESD circuit region is consistent with that of a TFT in the pixel region, the amount of the exposing light in the ESD circuit can be kept to be consistent with that in the pixel region. As a result, the problem that the GT PR thickness in the ESD circuit region is different from that in the pixel region can be resolved.

Furthermore, as shown in FIG. 4, the TFT in the ESD circuit region is formed with a plurality of small-sized sub-channels having the same channel length and the equivalent circuit of the sub-channels is equivalent to a plurality of devices connected in series. Therefore, when the ratio W/L of the TFT channel in the ESD circuit region is small, it is possible to reduce the possibility of increase of the turn-on current (Ion) and thus the driving capability can be improved while the gate-source capacitance Cgs and the gate-drain capacitance Cgd are increased accordingly due to the variation of W resulted from the deviation in the fabrication process. It should be noted that FIG. 4 shows three sub-channels, that is, the equivalent circuits equivalent to three devices connected in series, but the disclosed technology is not limited herewith.

In the embodiments of the disclosed technology, an array substrate is provided. The array substrate can comprise at least: a pixel region comprising at least one TFT having a channel; an ESD circuit region comprising at lest one TFT having a plurality of sub-channels connected in series, wherein each of the sub-channels of the TFT in the ESD circuit region has the same length, and the length of each of the sub-channels is identical to the channel length of the TFT in the pixel region.

In an illustrative example, the sub-channels of the TFT in the ESD circuit region comprise three sub-channels connected in series.

A method for fabricating an array substrate is also provided in an embodiment of the disclosed technology. The array substrate can comprise an ESD circuit region and a pixel region. The method can comprise: adjusting the amount of light for exposing of an exposure device so that the amount of the exposing light corresponding to the pixel region is identical to that corresponding to the ESD circuit region; and forming a channel of a TFT in the ESD circuit region and a channel of a TFT in the pixel region by a pattering process, wherein the channel of the TFT in the ESD circuit region comprise a plurality of sub-channels, and each of the sub-channels of the TFT in the ESD circuit region has the same length as the channel length of the TFT in the pixel region.

In addition, a liquid crystal display device is also provided in an embodiment of the disclosed technology. The liquid crystal display device can comprise an array substrate. The array substrate can comprise: a pixel region comprising at least one TFT having a channel; and an ESD circuit region comprising at lest one TFT having a plurality of sub-channels connected in series, wherein each of the sub-channels of the TFT in the ESD circuit region has the same length, and the length of each of the sub-channels is identical to the channel length of the TFT in the pixel region.

In an illustrative example, the sub-channels of the TFT in the ESD circuit region comprise three sub-channels connected in series.

It should be noted that the term “identical” refers to “identical substantially” rather than “identical completely.”

It should be appreciated that the embodiments described above are intended to illustrate but not limit the disclosed technology. Although the disclosed technology has been described in detail herein with reference to the preferred embodiments, it should be understood by those skilled in the art that the disclosed technology can be modified and some of the technical features can be equivalently substituted without departing from the spirit and scope of the disclosed technology.

What is claimed is:

1. A method for fabricating an array substrate, the array substrate comprising an electro-static discharge (ESD) circuit region and a pixel region, the method comprising:
adjusting the amount of light for exposing of an exposure device so that the amount of light for exposing corresponding to the pixel region is identical to that corresponding to the ESD circuit region; and
forming channels of a thin film transistor (TFT) in the ESD circuit region and a channel of a TFT in the pixel region by a pattering process,
wherein the channel of the TFT in the ESD circuit region comprises a plurality of sub-channels arranged in parallel, and each of the sub-channels of the TFT in the ESD circuit region has the same length as the length of the channel of the TFT in the pixel region.

2. The method for fabricating the array substrate according to claim 1, wherein the channel in the ESD circuit region comprises three sub-channels.

3. An array substrate comprising:
a pixel region comprising at least one TFT having a channel; and
an ESD circuit region comprising at lest one TFT having a plurality of sub-channels connected in series,
wherein each of the sub-channels of the TFT in the ESD circuit region has the same length, and the length of each of the sub-channels is identical to the length of the channel of the TFT in the pixel region.

4. The array substrate according to claim 3, wherein the channel of the TFT in the ESD circuit region comprises three sub-channels.

5. A liquid crystal display device comprising:
an array substrate comprising:
a pixel region comprising at least one TFT having a channel; and
an ESD circuit region comprising at lest one TFT having a plurality of sub-channels connected in series,
wherein each of the sub-channels of the TFT in the ESD circuit region has the same length, and the length of each of the sub-channels is identical to the length of the channel of the TFT in the pixel region.

6. The liquid crystal display device according to claim 5, wherein the channel of the TFT in the ESD circuit region comprises three sub-channels.
